(19) United States
(12) Patent Application Publication
(10) Pub. No.: US 2025/0120214 A1
(43) Pub. Date: Apr. 10, 2025

(54) MINIMIZING SPACE CHARGE FOR OPTICAL-ELECTRICAL DATA TRANSMISSIONS

(71) Applicant: NVIDIA Corporation, Santa Clara, CA (US)

(72) Inventors: Shai Cohen, Tel Aviv (IL); Liron Gantz, Tel Aviv (IL); Itamar Priel, Tel Aviv (IL)

(21) Appl. No.: 18/484,257

(22) Filed: Oct. 10, 2023

(51) Int. Cl. H01L 31/0352; G02B 6/12; G02B 6/122; H01L 31/0232; H01L 31/028

(52) U.S. Cl. CPC H10F 77/147; G02B 6/1228; H10F 77/413; G02B 2006/12123; H10F 77/122

(57) ABSTRACT

To improve an optical signal to electrical signal of a photodiode (PD) which is part of an integrated circuit, the PD can be modified to reduce noise and improve the gain bandwidth. In some aspects, the absorption region of the PD can utilize a non-rectangular geometry, for example, a clipped tapered geometry which can absorb the optical signal in more linearly than a rectangular geometry. In some aspects, the input optical signal can be split into two or more split optical signals, where each split optical signal is directed toward a different portion of the absorption region. The incident power of the optical signal transmitted to each respective portion of the absorption region can be reduced by dividing the incident power by the number of split optical signals thereby improving the gain and bandwidth saturation of each portion of the absorption region.

### TECHNICAL FIELD

This application is directed, in general, to optical detection and, more specifically, to efficient detection of strong high-speed optical signals.

### BACKGROUND

Optical to electrical communications is typically handled by implementing one or more types of photodiodes when implemented as an interface to an integrated circuit, or part of an integrated circuit. As the average transmitted optical power is increased, by methods such as increasing the light source intensity or higher modulations such as pulse amplitude modulation 4 (PAM4) the photodiode's bandwidth and gain begins to degrade due to a phenomena known as “gain saturation”. Gain saturation occurs where high optical power induces large spatial charge distribution in the photodiode's depletion region, which begins to mask the depletion field, thereby limiting the photodiode's ability to quickly accelerate and collect charge carriers. It would be beneficial to be able to increase the optical power in data transmissions while reducing gain saturation.

### SUMMARY

In one aspect, a photodiode (PD) is disclosed. In one embodiment, the PD includes (1) an optical coupler configured to receive an optical signal, and (2) an absorption region, configured to receive the optical signal from the optical coupler and convert the optical signal to an electrical signal, wherein the absorption region is of a non-rectangular geometry and the absorption region has a first portion capable of receiving the optical signal.

In a second aspect, an optical-electrical system is disclosed. In one embodiment, the optical-electrical system includes (1) an optical waveguide wherein at least part of the optical waveguide is located as part of an integrated circuit and a second end of the optical waveguide is configured to receive an optical signal, (2) an optical splitter, configured to have an input end optically coupled to a first end of the optical waveguide, and configured to have an output end optically coupled to a first split optical waveguide and a second split optical waveguide, (3) a first photodiode (PD) optical coupler optically coupled to the first split optical waveguide, (4) a second PD optical coupler optically coupled to the second split optical waveguide, and (5) an absorption region, configured to receive the optical signal and converting the optical signal to an electrical signal, wherein a first portion of the absorption region faces the first PD optical coupler and a second portion of the absorption region faces the second PD optical coupler, and where the first split optical waveguide transmits half of an incident power of the optical signal and the second split optical waveguide provides half of the incident power of the optical signal.

In a third aspect, an optical-electrical system is disclosed. In one embodiment, the optical-electrical system includes (1) an optical waveguide, and (2) a photodiode (PD), configured to receive an optical signal from the optical waveguide, wherein the PD comprises an optical coupler to the optical waveguide and at least one absorption region with an absorption portion facing the optical coupler, where the absorption region comprises one or more of a non-linear geometry or more than one absorption portion.

### BRIEF DESCRIPTION

Reference is now made to the following descriptions taken in conjunction with the accompanying drawings, in which:

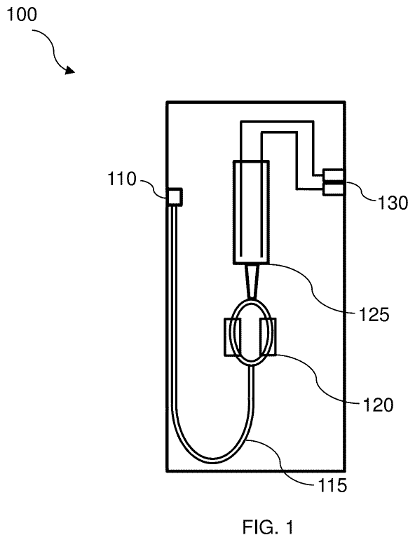

FIG. 1 is an illustration of a diagram of an example optical-electrical connection in an integrated circuit;

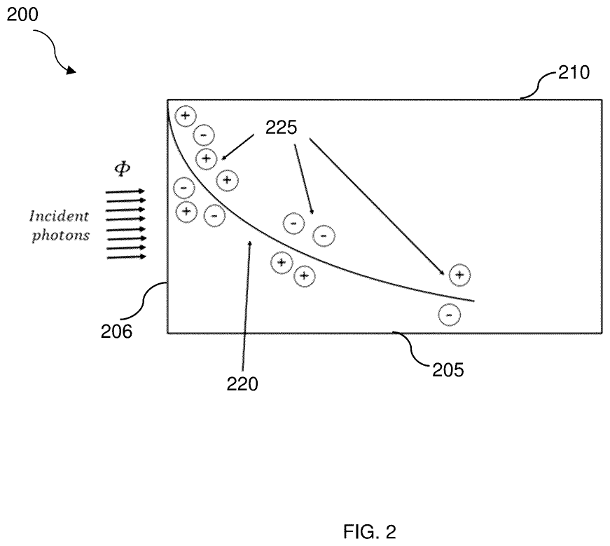

FIG. 2 is an illustration of a diagram of an example absorption curve of existing absorption regions;

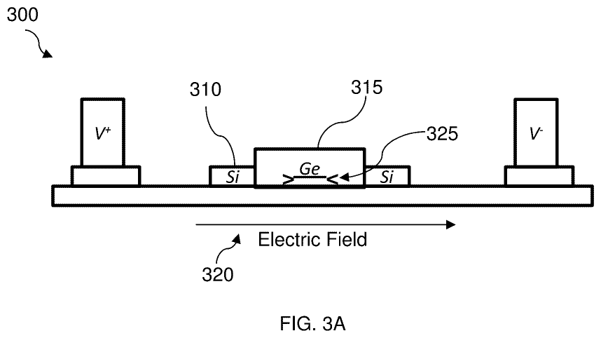

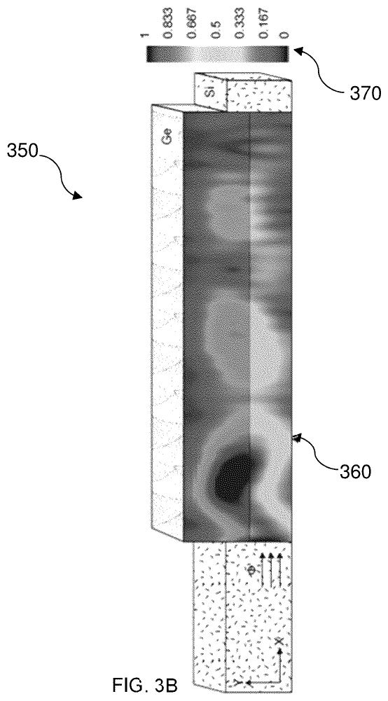

FIG. 3A is an illustration of a diagram of an example electrical field generated by an optical signal;

FIG. 3B is an illustration of a diagram of an example optical signal strength of a received optical signal;

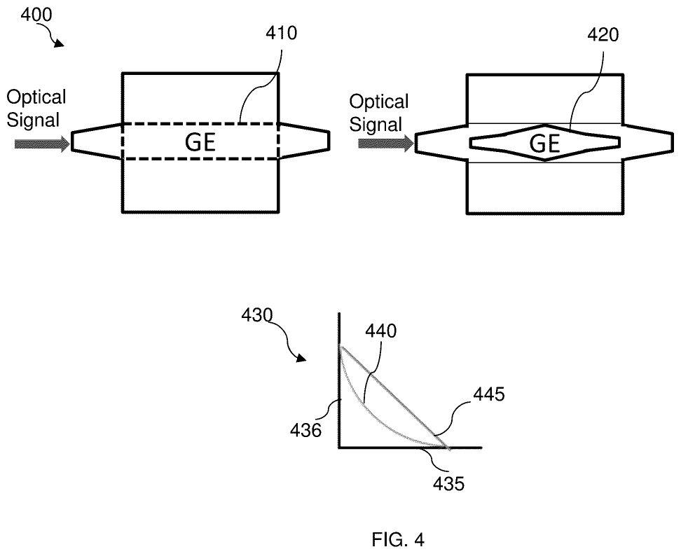

FIG. 4 is an illustration of a diagram of an example comparison of a conventional and new geometry of absorption regions;

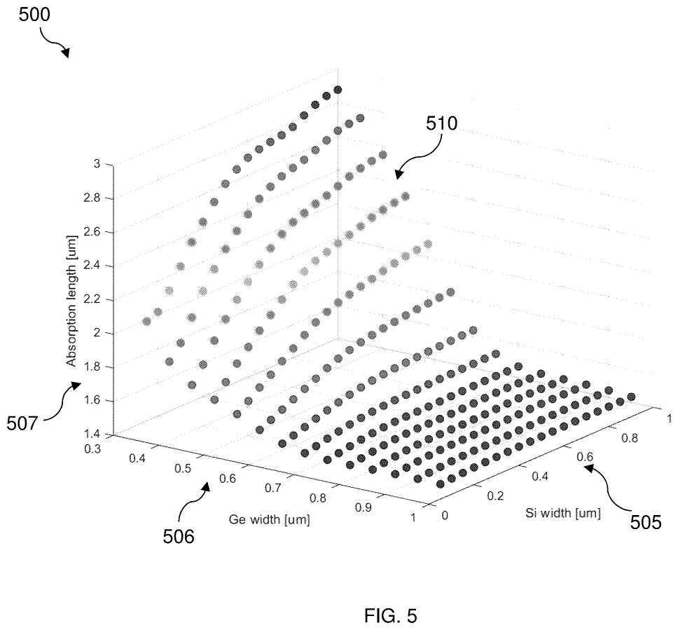

FIG. 5 is an illustration of a diagram of an example optical signal absorption varying with the silicon and germanium proportions;

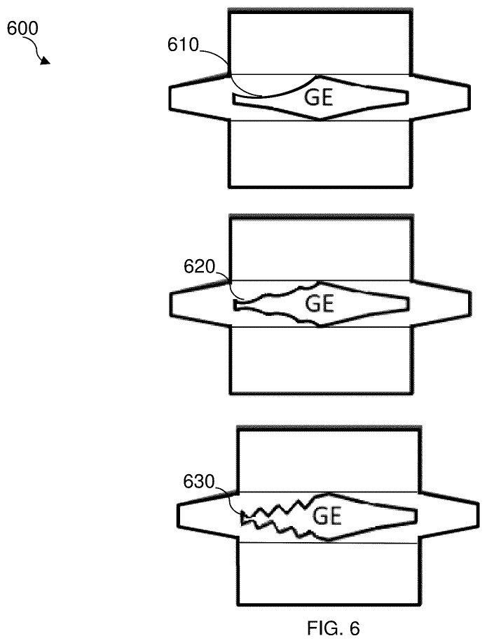

FIG. 6 is an illustration of a diagram of example non-rectangular geometries;

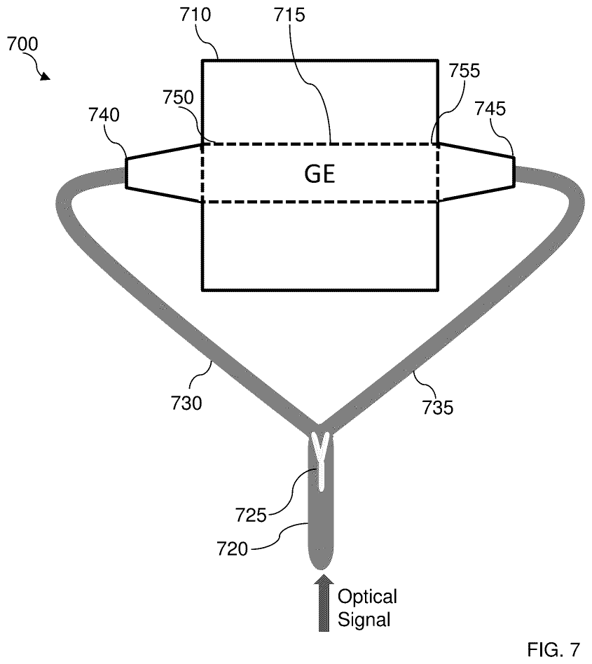

FIG. 7 is an illustration of a diagram of an example of using an optical splitter system prior to the optical signal being received by a PD;

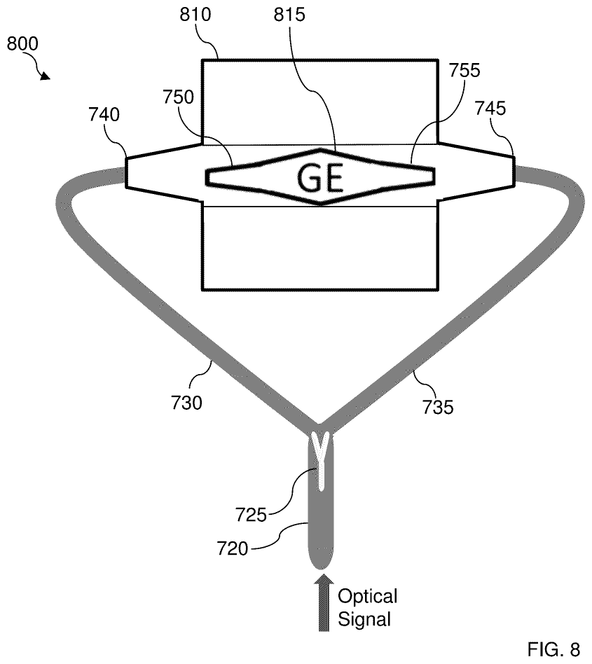

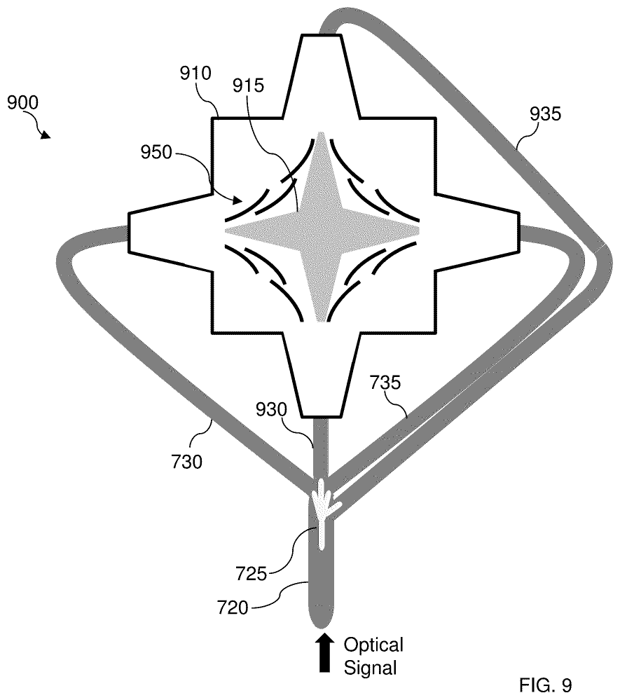

FIG. 8 is an illustration of a diagram of an example an optical splitter system with a different geometry of the absorption region;

FIG. 9 is an illustration of a diagram of an example an optical splitter system with complex absorption region geometries;

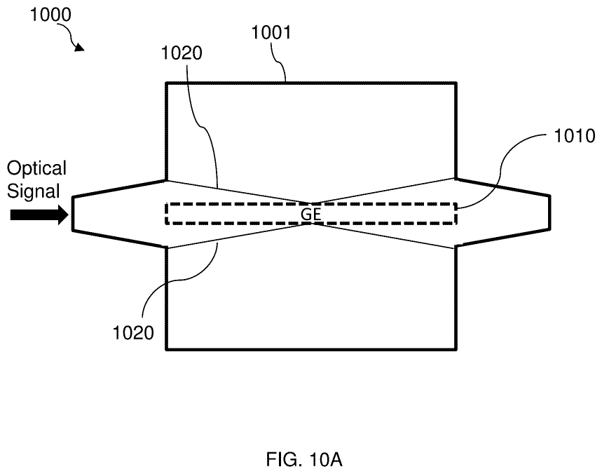

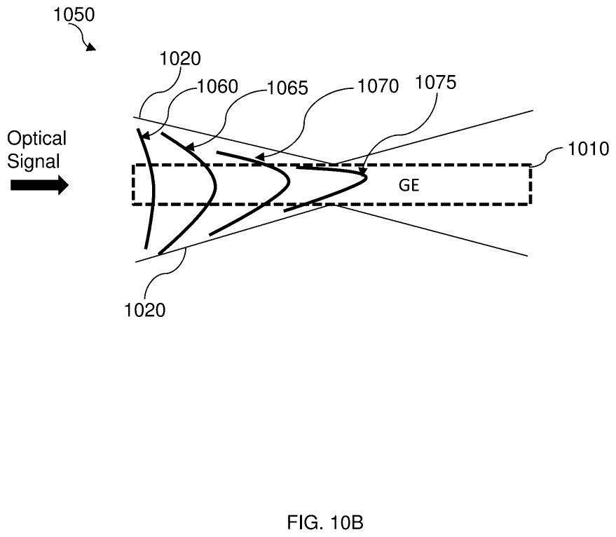

FIG. 10A is an illustration of a diagram of an example tapered waveguide; and

FIG. 10B is an illustration of a diagram of an example optical signal change using the tapered waveguide.

### DETAILED DESCRIPTION

In developing an integrated circuit (IC), there can be a requirement to interface the electrical portions of the IC with optical sources. An optical signal to an electrical receptor on the IC typically uses a germanium (Ge) absorption region which can generate an electrical charge utilizing the optical signal. As the optical signal interacts with the Ge, it can be exponentially absorbed and can excite generation of charge carriers. In some apparatuses the lateral p-type/intrinsic/n-type (PIN) junction can act as the multiplication region. As the charge carriers accelerate, they can excite secondary collisions leading to an amplification of the electrical signal.

The absorption region is typically part of a photodiode (PD). As the incident power of the optical signal is increased, the PD bandwidth and gain can begin to degrade, such as through gain saturation. Gain saturation can occur where high incident power of the optical signal induces a large spatial charge distribution in the PD depletion region (e.g., the PIN junction), which in turn can begin to mask the depletion field, thereby limiting the PD's ability to accelerate and collect charge carriers. This decay or depletion within the absorption region can follow Beer's Law that models the exponential decay in incident photons.

PDs as used within this disclosure include, for example, avalanche PDs (APDs), waveguide PDs (WGPDs), and waveguide APDs (WGAPDs). As the incident optical power is increased, the sensitivity of the absorption region can decrease.

This disclosure presents new apparatuses and systems to minimize the space charge effect of a PD thereby allowing a higher incident power of an optical signal to be transmitted while reducing gain bandwidth saturation. Typical PDs exhibit an exponential signal absorption pattern where a large portion of light is absorbed in a relatively shorth propagation distance, in which high carrier-density is generated and gain saturation worsens. It would be beneficial to have a linear decay of the optical signal with a constant proportion of photons being converted to electrons at each propagation distance.

As the absorption curve approaches linearization there is a more uniform absorption throughout the absorption region. Using an absorption equation, such as shown in Equation 1, while requiring a linear intensity profile, such as shown in Equation 2, the ideal absorption profile can be determined, such as shown in Equation 3.

$$\begin{matrix}Equation 1 : Example absorption equation & \\ \frac{dI ( z )}{dz} = - α ( z ) I ( z ) & \end{matrix}$$

$$\begin{matrix}Equation 2 : Example linear intensity profile & \\ I ( z ) = 1 - \frac{1 - β}{L} z & \end{matrix}$$

$$\begin{matrix}Equation 3 : Example ideal absorption profile & \\ α ( z ) = \frac{1 - β}{L - ( 1 - β ) Z} & \end{matrix}$$

where α(z) is the absorption coefficient as a function of z,
z is the position along the length of the absorption region,
I is the power of the optical signal as a function of position,
β is the desired fraction of the original incident power after a propagation distance of L along the absorption region, and
L is the propagation distance of the optical signal (AKA device length).

Using these equations, can result in a minimal absorption coefficient as shown by Equation 4, and a maximum absorption coefficient as shown by Equation 5. Using the below equations, where β=10⁻³, the minimum for an absorption coefficient using Ge can be

$$\frac{1}{{10}^{3} um} = {10}^{- 3} [ \frac{1}{um} ] .$$

The maximum for an absorption coefficient using Ge can be

$$\frac{1}{1} um ,$$

which can lead to a millimeter long device that can have bandwidth and noise implications (where the unit um is micrometers).

$$\begin{matrix}Equation 4 : Example minimum absorption coefficient & \\ α ( 0 ) ∼ \frac{1}{L} & \end{matrix}$$

$$\begin{matrix}Equation 5 : Example maximum absorption coefficent & \\ α ( L ) ∼ \frac{1}{β L} & \end{matrix}$$

The minimum and maximum absorption limits are idealized goals. Manufacturing techniques may not be able to achieve those limits and so a perfectly linear absorption pattern may not be able to be achieved when using Ge as the absorption region. Manufacturing techniques can approach those limits and so approach the linear absorption pattern. As the linear absorption pattern is approached, the space charge effect can be reduced and gain bandwidth increased.

Improving the absorption curve to move it closer in geometry to a linear relationship of incident power of the optical signal and the electrical charge generation, e.g., electron hole pairs (EHP), can be achieved by altering the geometry of the absorption region, splitting the optical signal, or a combination of the two processes.

A PD of an IC can include an optical coupler (i.e., an optical coupling) to a first end of an optical waveguide. The optical waveguide can be part of the IC or be external to the IC. The optical waveguide can receive an optical signal from a source outside of the IC (e.g., a fiber optic cable optically coupled to the IC), or a source internal of the IC. The absorption region of the PD can be aligned such that the optical signal is directed toward the absorption region through the optical coupler. The absorption region can be Ge or other types of materials that can react to the optical signal and generate an electrical signal by converting the optical signal.

The absorption region can utilize a non-rectangular geometry. In conventional PDs, the absorption region has rectangular geometry. More precisely, the absorption region can be called a rectangular parallelepiped, a rectangular cuboid, or a rectangular prism when interpreting the geometry in 3-dimensions (3D). In this disclosure, the term rectangular geometry includes the 3D terms named above.

The non-rectangular geometry can be applied to a portion of the absorption region, for example, having one end of the absorption region non-rectangular in shape. The non-rectangular geometry can absorb the optical signal at different incident powers or optical wavelengths along different parts of the absorption region portion. This can allow a greater total incident power of the optical signal to be used while maintaining or improving the conversion to the electrical signal, e.g., improving the gain bandwidth

The absorption region can utilize various types of non-rectangular geometry. In some aspects, the portion can utilize a non-rectangular geometry that can be a clipped tapered geometry, where the narrow end faces toward the optical coupler. In some aspects, the portion can utilize a non-rectangular geometry that can utilize a concave geometry, for example, dimples in the surface. The concave geometry can utilize circular patterns, straight edge geometries, or combinations thereof to improve the gain and bandwidth saturation point of the absorption region. In some aspects, the portion can utilize a non-rectangular geometry that can be triangular in shape. In some aspects, the portion can utilize a compound geometry, such as one or more of the geometries mentioned in various combinations, for example, using concave dimpled triangular geometries along a surface of a clipped tapered section.

A non-rectangular geometry of the portion of the absorption region can, in some aspects, allow for an off centering of the portion of the absorption region in respect to the optical coupler. For example, if a clipped tapered portion is utilized, one side of the clipped tapered portion can employ a steeper angle as compared to a different side of the clipped tapered portion. The clipped tapered portion can then be aligned off center to allow more optical signal to interact with the steeper side of the clipped tapered portion of the absorption region, and less optical signal to interact with the less steep side of the clipped tapered portion of the absorption region. The incident power of the optical signal can be effectively reduced for each portion of the optical signal interacting with absorption region, thereby improving the gain and bandwidth saturation of the conversion to the electrical signal. In some aspects, the portion of the absorption region can be centered with respect to the optical coupler.

The absorption region has an absorption coefficient that can vary along the non-rectangular portion of the absorption region (e.g., the non-rectangular region varies in thickness as the geometry varies). The absorption coefficient can describe how much light of a given color can be absorbed by the absorption region given a specific thickness. In some aspects, the absorption coefficient of the absorption region can satisfy or approach satisfying Equation 3. In some aspects, the portion of the absorption region utilizes a non-rectangular geometry that is a non-linear geometry while enabling a linear or near linear transmission signal absorption profile. For example, FIGS. 4, 6, and 9 demonstrate some potential non-linear geometry shapes for the portion of the absorption region facing the optical signal.

In some aspects, the portion of the absorption region can be a first portion and a second portion, where each portion faces a different optical coupler. In these aspects, an optical splitter can be positioned at a first end of the optical waveguide opposite a second of the optical waveguide, where the second end receives the optical signal from a source. An input end of the optical splitter can be optically coupled to the first end of the optical waveguide. An output end of the optical splitter can be a first split optical waveguide and a second split optical waveguide.

The PD can have two optical couplers, a first PD optical coupler and a second PD optical coupler. The first PD optical coupler can be optically coupled to the first split optical waveguide and the second PD optical coupler can be optically coupled to the second split optical waveguide. In aspects where the first portion faces the first PD optical coupler and the second portion faces the second optical coupler, the optical splitter enables half the incident power of the optical signal to be transmitted through the first split optical waveguide and a half of the incident power transmitted through the second split optical waveguide.

In some aspects, when using an optical splitter, the first portion and the second portion of the absorption region can utilize a rectangular geometry. In some aspects, when using an optical splitter, the first portion and the second portion of the absorption region can each utilize a non-rectangular geometry.

In some aspects, the optical splitter can utilize additional split waveguides, for example, four, six, eight, or other odd or even number of additional split optical waveguides. Each of the split optical waveguides (e.g., the first split optical waveguide, the second split optical waveguide, and the additional split optical waveguides), can be aligned and optically coupled to different respective PD optical couplers. In some aspects, the absorption region of the PD can have a separate portion facing each of the PD optical couplers (e.g., a first portion, a second portion, and additional portions), where the number of portions is equal to the number of split optical waveguides. In some aspects, the optical splitter can transmit the optical signal through each split waveguide using a reduced incident power. In some aspects, the reduced incident power can be equal to the total incident power (e.g., original incident power) of the optical signal divided by the number of split optical waveguides.

In some aspects, where there are more than two portions, the geometry of the absorption region can be arranged in a regular pattern, such as in a 2D visualization of a diamond pattern, a star pattern, or other pattern. In some aspects, the geometry of the absorption region can be arranged in an irregular pattern, for example, one portion being clipped tapered, one portion clipped tapered and offset from a center alignment, one portion having a concave geometry, and other combinations.

In some aspects, the PD can be part of an optical-electrical system, such as part of an IC. In some aspects, the optical waveguide can be external to the IC and the PD located as part of the IC. In some aspects, part of the optical waveguide can be part of the IC and part of the optical waveguide can be external of the IC. In some aspects, the optical splitter can be part of the IC. In some aspects, the source of the optical signal can be part of the IC and the PD is part of the IC. In some aspects, the source of the optical signal is external to the IC.

In some aspects, the IC can be a complementary metal-oxide semiconductor (CMOS) chip, a memory chip, a central processing unit (CPU) chip, or a graphics processing unit (GPU) chip. In some aspects, the PD can be an APD, a WGAPD, or a WGPD.

Turning now to the figures, FIG. 1 is an illustration of a diagram of an example optical-electrical connection in an IC 100. IC 100 represents part of an IC that can contain one or more other components or systems. For example, IC 100 can be part of a CMOS chip, a memory chip, a CPU, a GPU, or other types of IC chips.

IC 100 includes an optical input 110 coupled to an optical waveguide 115 that routes a received optical signal to a modulation unit 120. Modulation unit 120 can apply one or more modulations, such as PAM4 to the optical signal. If an optical splitter is used, the optical splitter can be located at the output end of modulation unit 120. PD 125 can be optically coupled to modulation unit 120. PD 125 can utilize an absorption region with a non-rectangular geometry or can support multiple optical coupler points each with a separate portion of the absorption region. PD 125 is electrically coupled to electrical output 130 which allows the converted electrical signal generated from the absorption region to be transmitted to other parts of the IC, or other chips or systems.

FIG. 2 is an illustration of a diagram of an example absorption curve 200 of existing absorption regions. Absorption curve 200 shows an exponential decay of optical power in the absorption region and a demonstration of the generation of EHPs. As the optical signal propagates into the absorption region, it decays at an exponential rate, and is modeled with the coefficient α, which dictates the rate of decay (e.g., a larger α→quicker decay).

Absorption curve 200 is derived from Beer-Lambert's law, which shows that the radiant flux of the light which emergers from an infinitesimal slice (dz) of the material is reduced, (compared to that of the light which entered the slice dz) and is governed by the first order differential equation

$$\frac{dI}{dz} = - α I ( z ) .$$

It is generally assumed that a is constant, thus yielding the solution I(z)=I₀^{-αz}. When the optical signal is strong, it can result in significant space charge density being generated in first 1-2 absorption lengths of the absorption region, where I is the intensity of the optical signal.

Absorption curve 200 has an x-axis 205 showing the distance the optical signal propagates through an absorption region 210. A y-axis 206 shows the optical signal intensity. A curve 220 shows the exponential drop in optical intensity as the optical signal propagates through the absorption region. EHPs 225 demonstrate that more excitation of electrons occurs earlier in the propagation process than later.

FIG. 3A is an illustration of a diagram of an example functional view 300 of an electrical field generated by an optical signal. Functional view 300 is demonstrated using a Ge absorption region 315 within a silicon (Si) layer 310 on an IC. Electrical field 320 can be generated from the receipt of an optical signal at the Ge absorption region 315. Space charge area 325 demonstrates that a decay of the transformation of the optical signal to the electrical signal is occurring as the bandwidth becomes saturated. This further demonstrated visually in FIG. 3B.

FIG. 3B is an illustration of a diagram of an example functional view 300 of electrical relative signal strength of a received optical signal. Absorption region 360 demonstrates the decay in moving from left to right along the length of absorption region 360. Key 370 shows the relative energy absorption. This shows a conventional PD absorption pattern.

When examining the case of a lateral waveguide integrated PD, the absorption pattern demonstrates a space charge effect. The charge density generated by the incident optical signal effectively creates an electric field which begins to mask the electric field which is externally applied to the device, thus degrading the speed and collection of the electrical signal.

FIG. 4 is an illustration of a diagram of an example comparison 400 of a conventional and new geometry as disclosed herein of absorption regions. Comparison 400 shows a conventional absorption region 410 of a PD and a clipped tapered absorption region 420 of a PD. Clipped tapered absorption region 420 has a narrower portion facing the optical coupler and a wider portion toward the middle of clipped tapered absorption region 420. An optical signal is received by each respective absorption region as shown by the block arrow.

A chart 430 demonstrates the absorption curve for each type of absorption region. Chart 430 has an x-axis of the propagation length and a y-axis of the remaining optical power. Chart 430 demonstrates that conventional absorption region 410 can result in an absorption curve that resembles curve 440. The amount of optical power able to be absorbed drops quickly over the propagation distance. Clipped tapered absorption region 420 can result in an absorption curve that resembles curve 445. Curve 445 shows that the absorption curve is close to being linear over the propagation distance. This can lead to improvement in gain and bandwidth saturation at higher optical powers, thereby allowing a higher rate of transmission of the optical signal.

FIG. 5 is an illustration of a diagram of an example optical signal absorption 500 varying with the Si and Ge proportions. Optical signal absorption 500 demonstrates a sample absorption pattern using Ge as the absorption region and where the absorption region utilizes a clipped tapered geometry, such as clipped tapered absorption region 420. Optical signal absorption 500 has an x-axis 505 of the Si width in micrometers, a y-axis 506 of the Ge width in micrometers, and a z-axis 507 of the absorption length in micrometers.

Using a clipped tapered absorption region, optical signal absorption 500 shows that the length of the absorption region can be determined, as well as the start and end widths of the absorption region that would satisfy α(z) (absorption coefficient) as defined in Equations 3, 4, and 5. The geometry of the clipped tapered region, such as shown in clipped tapered absorption region 420, can be refined using the start and end widths to achieve further improvements. Repeating the testing can provide further refinement of the varying thicknesses and geometries of the absorption regions.

FIG. 6 is an illustration of a diagram of example non-rectangular geometries 600. The absorption region can be of any type of geometry, simple or complex. A geometry 610 shows a clipped tapered absorption region (e.g., a first portion of the absorption region) that is offset from the center alignment of the optical coupler. Geometry 610 also is demonstrating the bottom side of the clipped tapered region being fairly straight, and a top side that is concave in shape. A geometry 620 shows a dimpled surface on a first portion of the absorption region, and a regular tapered region on a second portion of the absorption region. A geometry 630 shows an angled cut surface on a first portion of the absorption region, and a regular tapered region on a second portion of the absorption region. The absorption region can be one or more combinations of geometry to achieve the highest efficiency for the working conditions and type of optical signals being used.

FIG. 7 is an illustration of a diagram of an example of using an optical splitter system 700 prior to the optical signal being received by a PD. Optical splitter system 700 demonstrates that splitting a received optical signal can also reduce the incident power received, for each part of the split optical signal. A reduced incident power can allow a higher gain bandwidth, lower noise, and lower space charge effect at the absorption region. This in turn can allow an improved transmission gain and bandwidth saturation and a higher transmission rate of the optical signal.

Optical splitter system 700 has a PD 710 with an absorption region 715. Absorption region 715 can be Ge or another material or medium. An optical signal can be received by an optical waveguide 720. Optical waveguide 720 can be part of the same IC as PD 710, part of a different system, or be a separate component. Optical waveguide 720 is optically coupled to an optical splitter 725. Optical splitter 725 can be part of the same IC as PD 710, part the same component as optical waveguide 720, part of a different system, or be a separate component.

The output ends of optical splitter 725 are respectively optically coupled to a first split optical waveguide 730 and a second split optical waveguide 735. In some aspects, there can be one or more additional split optical waveguides where optical splitter 725 splits the optical signal into the three or more, respectively, optical signals. Each respective optical signal, in each split waveguide, has a reduced incident power. In some aspects, the reduced incident power of the optical signal is equal to the total incident power (e.g., the original incident power) divided by the number of split optical waveguides used in optical splitter system 700.

First split optical waveguide 730 is coupled to a first PD optical coupler 740. The optical signal transmitted through first split optical waveguide 730 is directed toward a first portion 750 of absorption region 715. First portion 750 can absorb the optical signal and thereby transform it into an electrical signal that can be further propagated to other parts of the IC, or to other systems or chips.

Second split optical waveguide 735 is coupled to a second PD optical coupler 745. The optical signal transmitted through second split optical waveguide 735 is directed toward a second portion 755 of absorption region 715. Second portion 755 can absorb the optical signal and thereby transform it into an electrical signal that can be further propagated to other parts of the IC, or to other systems or chips. In some aspects where additional split optical waveguides are utilized, additional PD optical couplers can be present and additional portions of absorption region 715 can be utilized.

FIG. 8 is an illustration of a diagram of an example an optical splitter system 800 with a different geometry of the absorption region. Optical splitter system 800 is similar to optical splitter system 700 with the exceptions noted below. Optical splitter system 800 demonstrates a combination of techniques of using an optical splitter and using a non-rectangular geometry for the absorption region. The non-rectangular geometry can improve optical signal absorption for a given incident power. The optical splitter can reduce the incident power. The combination of improvements can allow a higher gain bandwidth, lower noise, and lower space charge effect at the absorption region. This in turn can allow an improved transmission gain and bandwidth saturation point and a higher transmission rate of the optical signal.

Optical splitter system 800 is similar to optical splitter system 700 where the absorption region is replaced with an absorption region 815 in a PD 810. Absorption region 815 has two clipped tapered portions, each portion facing a respective PD optical coupler.

FIG. 9 is an illustration of a diagram of an example an optical splitter system 900 with complex absorption region geometries. Optical splitter system 900 is similar to optical splitter system 800 with the addition of two additional split optical waveguides, third split optical waveguide 930 and fourth split optical waveguide 935. The absorption region of a PD 910 is represented by an absorption region 915 with four portions, where each portion faces a respective PD optical coupler and a split waveguide. In FIG. 9 the four portions are non-rectangular but one or more of the different portions can also be rectangular.

Each portion of absorption region 915 can have 25% of the original incident power directed toward the clipped tapered absorption portion. Electric field 950 demonstrates how the electrical charges can be generated.

FIG. 10A is an illustration of a diagram of an example tapered waveguide 1000 of a PD 1001. In some aspects, tapered waveguide 1000 can utilize the rectangular geometry absorption region. In some aspects, tapered waveguide 1000 can utilize a non-rectangular geometry absorption region. Tapered waveguide 1000 angles the waveguide within PD 1001 to alter the optical signal. By tapering the waveguide inward, the optical signal can be condensed as it progresses through PD 1001, thereby increasing the overlap between the optical signal and the absorption region as it progresses through PD 1001. This can have a similar beneficial effect as tapering the absorption region itself. Since the optical signal is continually diminishing in intensity as it progress through PD 1001, the increased signal absorption helps to maintain an approximately constant number of photons absorbed by the absorption region. This is different than a constant percentage of the total optical signal.

Tapered waveguide 1000 has an absorption region 1010 that has a rectangular geometry. Optical waveguides 1020 within PD 1001 are angled toward the center of absorption region 1010. In some aspects, PD optical waveguide of PD 1001 can be tapered such that there is a first end of the PD optical waveguide that has a larger distance to absorption region 1010 than a second end of the PD optical waveguide. The first end can be closer to the optical coupler than the second end, and the second end can be closer to a middle of the absorption region than the first end (as shown in FIG. 10A). This aspect can achieve the same outcome in increasing the absorption coefficient as the optical signal progresses through PD 1001 by tapering the waveguide rather than tapering absorption region 1010.

FIG. 10B is an illustration of a diagram of an example optical signal change 1050 using tapered waveguide 1000 of PD 1001 in FIG. 10A. Building on tapered waveguide 1000, optical signals 1060, 1065, 1070, and 1075 are shown overlaid on optical waveguides 1020 and absorption region 1010. As the optical signal progresses through PD 1001, the optical power distribution can become more concentrated into absorption region 1010. The total number of photons (i.e., the total optical signal power) can be diminished.

For example, optical signal 1060 can represent 100 photons, optical signal 1065 can represent 75 photons, optical signal 1070 can represent 50 photons, and optical signal 1075 can represent 25 photons. Even though there are less photons in total as the optical signal progress through PD 1001, the optical signal is forced, by optical waveguides 1020, into a stronger interaction (via a larger overlap) with absorption region 1010.

A portion of the above-described apparatus, systems or methods may be embodied in or performed by various digital data processors or computers, wherein the computers are programmed or store executable programs of sequences of software instructions to perform one or more of the steps of the methods. The software instructions of such programs may represent algorithms and be encoded in machine-executable form on non-transitory digital data storage media, e.g., magnetic or optical disks, random-access memory (RAM), magnetic hard disks, flash memories, and/or read-only memory (ROM), to enable various types of digital data processors or computers to perform one, multiple or all of the steps of one or more of the above-described methods, or functions, systems or apparatuses described herein. The data storage media can be part of or associated with the digital data processors or computers.

The digital data processors or computers can be comprised of one or more GPUs, one or more CPUs, one or more of other processor types, or a combination thereof. The digital data processors and computers can be located proximate each other, proximate a user, in a cloud environment, a data center, or located in a combination thereof. For example, some components can be located proximate the user and some components can be located in a cloud environment or data center.

The GPUs can be embodied on a single semiconductor substrate, included in a system with one or more other devices such as additional GPUs, a memory, and a CPU. The GPUs may be included on a graphics card that includes one or more memory devices and is configured to interface with a motherboard of a computer. The GPUs may be integrated GPUs (iGPUs) that are co-located with a CPU on a single chip.

Portions of disclosed examples or embodiments may relate to computer storage products with a non-transitory computer-readable medium that have program code thereon for performing various computer-implemented operations that embody a part of an apparatus, device or carry out the steps of a method set forth herein. Non-transitory used herein refers to all computer-readable media except for transitory, propagating signals. Examples of non-transitory computer-readable media include, but are not limited to: magnetic media such as hard disks, floppy disks, and magnetic tape; optical media such as CD-ROM disks; magneto-optical media such as floppy disks; and hardware devices that are specially configured to store and execute program code, such as ROM and RAM devices. Configured or configured to means, for example, designed, constructed, or programmed, with the necessary logic and/or features for performing a task or tasks. Examples of program code include both machine code, such as produced by a compiler, and files containing higher level code that may be executed by the computer using an interpreter.

In interpreting the disclosure, all terms should be interpreted in the broadest possible manner consistent with the context. In particular, the terms “comprises” and “comprising” should be interpreted as referring to elements, components, or steps in a non-exclusive manner, indicating that the referenced elements, components, or steps may be present, or utilized, or combined with other elements, components, or steps that are not expressly referenced.

Those skilled in the art to which this application relates will appreciate that other and further additions, deletions, substitutions and modifications may be made to the described embodiments. It is also to be understood that the terminology used herein is for the purpose of describing particular embodiments only, and is not intended to be limiting, since the scope of the present disclosure will be limited only by the claims. Unless defined otherwise, all technical and scientific terms used herein have the same meaning as commonly understood by one of ordinary skill in the art to which this disclosure belongs. Although any methods and materials similar or equivalent to those described herein can also be used in the practice or testing of the present disclosure, a limited number of the exemplary methods and materials are described herein.

What is claimed is:

1. A photodiode (PD), comprising:
an optical coupler configured to receive an optical signal; and
an absorption region, configured to receive the optical signal from the optical coupler and convert the optical signal to an electrical signal, wherein the absorption region is of a non-rectangular geometry and the absorption region has a first portion capable of receiving the optical signal.

2. The PD as recited in claim 1, wherein the absorption region is comprised of germanium (Ge).

3. The PD as recited in claim 1, wherein the first portion of the absorption region utilizes a clipped tapered geometry.

4. The PD as recited in claim 1, wherein the first portion of the absorption region utilizes a concave geometry.

5. The PD as recited in claim 1, wherein the first portion of the absorption region is a triangular geometry.

6. The PD as recited in claim 1, wherein the first portion of the absorption region utilizes a compound geometry.

7. The PD as recited in claim 1, wherein the first portion of the absorption region is centered with respect to the optical coupler.

8. The PD as recited in claim 1, wherein the first portion of the absorption region is off-centered with respect to the optical coupler.

9. The PD as recited in claim 1, wherein an absorption coefficient of the absorption region satisfies
$$α ( z ) = \frac{1 - β}{L - ( 1 - β ) Z} .$$

10. The PD as recited in claim 1, wherein the first portion of the absorption region utilizes a non-linear geometry while enabling a near linear transmission signal absorption profile.

11. The PD as recited in claim 1, wherein the PD is one of an avalanche PD (APD), a waveguide integrated APD (WGAPD), or a waveguide integrated PD (WGPD).

12. An optical-electrical system, comprising:
an optical waveguide wherein at least part of the optical waveguide is located as part of an integrated circuit and a second end of the optical waveguide is configured to receive an optical signal;
an optical splitter, configured to have an input end optically coupled to a first end of the optical waveguide, and configured to have an output end optically coupled to a first split optical waveguide and a second split optical waveguide;
a first photodiode (PD) optical coupler optically coupled to the first split optical waveguide;
a second PD optical coupler optically coupled to the second split optical waveguide; and
an absorption region, configured to receive the optical signal and converting the optical signal to an electrical signal, wherein a first portion of the absorption region faces the first PD optical coupler and a second portion of the absorption region faces the second PD optical coupler, and where the first split optical waveguide transmits half of an incident power of the optical signal and the second split optical waveguide provides half of the incident power of the optical signal.

13. The optical-electrical system as recited in claim 12, wherein the first portion of the absorption region and the second portion of the absorption region each form a non-rectangular geometry.

14. The optical-electrical system as recited in claim 12, wherein the optical splitter splits the optical signal into additional split optical waveguides, each of the additional split optical waveguides is optically coupled to a respective additional PD optical coupler, the absorption region has additional portions of the absorption region equal in number to a number of additional split optical waveguides, where each additional portion of the absorption region is aligned with the respective of each additional PD optical coupler, and the first split optical waveguide, the second split optical waveguide, and the additional split optical waveguides transmits a reduced incident power of the optical signal equal to a total incident power of the optical signal divided by a number of split optical waveguides that includes the first split optical waveguide, the second split optical waveguide, and each of the additional split optical waveguides.

15. The optical-electrical system as recited in claim 14, wherein the absorption region has four, six, or eight absorption portions.

16. The optical-electrical system as recited in claim 12, wherein the integrated circuit is a complementary metal-oxide semiconductor (CMOS) chip, a memory chip, central processing unit (CPU) chip, or a graphics processing unit (GPU) chip.

17. A optical-electrical system comprising:
an optical waveguide; and
a photodiode (PD), configured to receive an optical signal from the optical waveguide, wherein the PD comprises an optical coupler to the optical waveguide and at least one absorption region with an absorption portion facing the optical coupler, where the absorption region comprises one or more of a non-linear geometry or more than one absorption portion.

18. The optical-electrical system as recited in claim 17, wherein the more than one absorption portion comprises two, four, or six absorption portions and further comprises:
an optical splitter, configured to split the optical signal into a number of split optical signals as respective absorption portions, where each of the number of split optical signals has an incident power equal to a total incident power of the optical signal divided by the number of split optical signals.

19. The optical-electrical system as recited in claim 18, wherein each of the more than one absorption portion utilizes the non-linear geometry.

20. The optical-electrical system as recited in claim 17, wherein the non-linear geometry utilizes a tapered geometry with a narrower portion of the absorption region facing the optical coupler.

21. The optical-electrical system as recited in claim 17, wherein the optical-electrical system is located as part of an integrated circuit.

22. The optical-electrical system as recited in claim 17, wherein the PD is one of an avalanche PD (APD), a waveguide integrated APD (WGAPD), or a waveguide integrated PD (WGPD).

23. The optical-electrical system as recited in claim 17, wherein the absorption region is more than one absorption portion, and a PD optical waveguide of the PD is tapered with a first end of the PD optical waveguide having a larger distance to the absorption region than a second end of the optical waveguide, where the first end is closer to the optical coupler than the second end, and the second end is closer to a middle of the absorption region than the first end.

24. The optical-electrical system as recited in claim 23, wherein the PD optical waveguide is a first PD optical waveguide, and additional PD optical waveguides are present within the PD.

25. The optical-electrical system as recited in claim 17, wherein the optical-electrical system is part of a complementary metal-oxide semiconductor (CMOS) chip, a memory chip, a central processing unit (CPU) chip, or a graphics processing unit (GPU) chip.
